(19) United States
(12) Patent Application Publication
(10) Pub. No.: US 2007/0126485 A1
(43) Pub. Date: Jun. 7, 2007

(54) Voltage-controlled oscillator

(76) Inventors: Yuichi Tateyama, Tokyo (JP); Takashi Otsuka, Kanagawa (JP)

Correspondence Address: MCDERMOTT WILL & EMERY LLP, 600 13TH STREET, N.W., WASHINGTON, DC, 20005-3096, US

(21) Appl. No.: 11/595,899

(22) Filed: Nov. 13, 2006

(30) Foreign Application Priority Data
Dec. 7, 2005 (JP) 2005-352988

(51) Int. Cl. H03L 7/06

(52) U.S. Cl. 327/156

(57) ABSTRACT

To provide a provide a voltage-controlled oscillator capable of controlling the threshold voltage of a MOS transistor independently of a temperature compensation control signal and an external voltage frequency control signal while securing linearity and downsizing the oscillator size without reducing the variable range of frequency, the voltage-controlled oscillator includes an amplifier, a piezoelectric vibrator, and a first load capacitor and a second load capacitor arranged as the load capacitors between both terminals of the piezoelectric vibrator, wherein a capacitor provided as the first load capacitor is composed of a variable capacitor with a small change in capacitance with respect to an input voltage and a capacitor provided as the second load capacitor is composed of a variable capacitor with a large change in capacitance with respect to an input voltage. This makes it possible to arbitrarily determine the output bias of a temperature compensation control circuit and an external voltage frequency control circuit.

### BACKGROUND OF THE INVENTION

1. Field of the Invention

The present invention relates to a voltage-controlled oscillator, and in particular to a voltage-controlled oscillator used as a temperature-compensated crystal oscillator that is based on voltage control.

2. Description of the Related Art

In recent years, with rapid development of mobile communication devices such as cell phones, these communication devices are requested to add various functions including the temperature compensation function, compact size, and use of higher frequencies. As a result, same as the communication devices, crystal oscillators used as a reference of communication frequency are also requested to add the temperature compensation function, compact size, and use of higher frequencies.

A temperature-compensated crystal oscillator is a crystal oscillator equipped with a temperature compensation function and whose change in frequency caused by a change in temperature is reduced and is widely used as a source of reference frequency of a cell phone. A voltage-controlled oscillator is an oscillator that includes a variable capacitor element capable of changing a capacitance value with a voltage as a load capacitor in an oscillation loop and controls the terminal voltage of the variable capacitor element to change the load capacitance value to control the frequency. A temperature-compensated crystal oscillator is known that controls the terminal voltage of a variable capacitor in a voltage-controlled oscillator to cancel the temperature characteristic of a crystal vibrator (piezoelectric vibrator).

In recent years, temperature-compensated crystal oscillators have undergone efforts to reduce phase noise, shorten the activation time and perform highly accurate temperature compensation as well as downsize the system. To reduce the size of the crystal oscillator, it is mandatory to downsize the crystal vibrator. In general, the ratio of change in the frequency to a change in the variable capacitance is reduced as the crystal vibrator is downsized.

It is thus necessary to increase the change in the capacitance with respect to the control voltage of a variable capacitor used as a load capacitor. For example, as described in JP-A-2003-318417 and JP-A-11-220329, by using an electrostatic capacitance generated between the source and drain terminals and the gate terminal of a MOS transistor with the source terminal and drain terminal short-circuited, it is possible to increase the change in the capacitance with respect to a change in the control voltage, thereby improving the sensitivity of a change in the frequency of a crystal oscillator (refer to FIG. 16).

For example, there is proposed an exemplary voltage-controlled oscillator shown in FIG. 19 comprising a feedback resistor 6, an amplifier 1 including an inverter, a piezoelectric vibrator 4, and first and second MOS transistors connected as variable capacitors to both terminals of the piezoelectric vibrator. The source terminal is short-circuited with the drain terminal of each of the first and second MOS transistors working as a variable capacitor. An electrostatic capacitance generated between the source and drain terminals and the gate terminal of each of the first and second MOS transistors is controlled by way of a voltage source 9 connected to the gate terminal.

The voltage-controlled oscillator directly connects, as a load capacitance, an electrostatic capacitance generated between the source and drain terminals and the gate terminal of the MOS transistor to the amplifier and crystal oscillator (piezoelectric vibrator) of the oscillator circuit and controls the gate voltage of a MOS transistor to change the electrostatic capacitance generated between the source and drain terminals and the gate terminal thus controlling the frequency. In this case, when the gate voltage of the MOS transistor has reached the voltage across the source and drain terminals plus threshold voltage, a channel is formed just below a gate oxide film, thus increasing the electrostatic capacitance between the gate terminal and the channel or the electrostatic capacitance between the source and grain terminal (this voltage is also called a capacitance switching voltage).

A first problem with the related art voltage-controlled oscillator is that the an abrupt change in frequency takes place when the capacitance value switches near the capacitance switching voltage, thus making it difficult to ensure the linearity. This is because the frequency-capacitance characteristic of a piezoelectric vibrator shows an exponential curve and a larger difference of capacitance value between when the capacitance value is below the capacitance switching voltage and when the capacitance value is above the capacitance switching value results in a larger variable range of the frequency with respect to the change in capacitance.

A second problem is that the DC bias of the source and drain terminals is determined by the amplifier of the oscillator circuit thus it is impossible to set the capacitance switching value to an arbitrary value resulting in failure to control the frequency around an arbitrary gate voltage.

A third problem is that the capacitance switching voltage changes dependently on variations in the threshold voltage and temperature characteristic of a MOS transistor in a normal CMOS process and that it is necessary to provide a temperature compensation control signal and an external voltage frequency control signal with a characteristic to cancel the threshold voltage and temperature characteristic of a MOS transistor.

Further, a fourth problem is that a capacitance value is large when it is below the capacitance switching voltage resulting in a smaller frequency variable range and slower frequency activation time.

In order to facilitate the design of a crystal oscillator that uses an electrostatic capacitance generated between the source and drain terminals and the gate terminal of a MOS transistor and put the crystal oscillator in commercial use, it is necessary to increase the electrostatic capacitance generated between the terminals of a MOS transistor to cause a mild change in the capacitance value or increase the electrostatic capacitance by using an array structure to and control the threshold voltage control signal independently of a temperature compensation control signal and an external voltage frequency control signal.

### SUMMARY OF THE INVENTION

The invention has been accomplished in view of the above circumstances. An object of the invention is to provide a voltage-controlled oscillator that secures linearity and downsize the oscillator size without reducing the variable range of frequency.

That is, an object of the invention is to provide a voltage-controlled oscillator capable of improving characteristics by preventing an increase in the capacitance value below the capacitance switching voltage of an electrostatic capacitance generated between the terminals of a MOS transistor, keeping the ratio of change in the frequency caused by an external input voltage to a constant value within a large variable range, as well as controlling the threshold voltage of a MOS transistor at the same time.

In order to attain the above object, the invention provides a voltage-controlled oscillator comprising: an amplifier including a bipolar transistor or a CMOS transistor and a feedback resistor; a piezoelectric vibrator; and a load capacitor 1 and a load capacitor 2 arranged as the load capacitors between both terminals of the piezoelectric vibrator; wherein a variable capacitor with a small change in capacitance with respect to an input voltage is used for the load resistor 1 means and wherein a variable capacitor with a large change in capacitance with respect to an input voltage is used for the load resistor 2 means.

With this configuration, by combining the load capacitors 1 and 2 having different load capacitance change values with respect to an input voltage, it is possible to secure the variable frequency range below a capacitance switching voltage and also above the capacitance switching voltage. This allows expansion of the variable frequency range with respect to an input voltage (refer to FIG. 16).

The invention provides a voltage-controlled oscillator comprising variable capacitor means consisting of first and a second DC cut capacitors as the load capacitor 1 means composed of a first MOS transistor and has a variable capacitor provided as the load capacitor 2 means composed of a second and a third MOS transistors. The source and drain terminals of the second MOS transistor of the load capacitor 2 means are connected to one end of the piezoelectric vibrator. The other end of the piezoelectric vibrator is connected to the source and drain terminals of the third MOS transistor of the load capacitor 2 means and the gates of the second and third MOS transistor are connected in common.

With this configuration, the switching voltage of the MOS transistors constituting the load capacitor 1 and 2 means differs between the second and the third MOS transistors, which increases the frequency variable range and improves linearity. The phase difference between the gate terminal and the source and drain terminals of the first MOS transistor of the load capacitor 1 means is approximately 180 degrees. Due to the Miller effect, the capacitance of the MOS variable capacitor (varactor) is equivalent to approximately double the capacitance value, thus downsizing the system compared with the capacitance value required to vary the frequency. Further, it is possible to provide a large ratio of a change in frequency to a change in the control voltage of the MOS varactor, a so-called a frequency variable sensitivity.

The invention provides a voltage-controlled oscillator wherein the oscillating voltages of opposite phases are applied to the source and drain terminals and the gate terminal of the first MOS transistor of the load capacitor 1 means and the first control signal input to the gate terminal of the first MOS transistor of the load capacitor 1 means and a second control signal input to the gate terminals of the second and third MOS transistors of the load capacitor 2 are used to control the oscillating frequency.

With this configuration, the capacitance switching voltages of MOS transistors constituting the load capacitor 1 and 2 means change respectively thus increasing the frequency variable range and improving linearity. By using the first and second control signals that can be controlled independently, it is possible to control a MOS transistor threshold voltage and control the capacitance switching voltage thus varying the frequency around an arbitrary control voltage value. The phase difference between the gate terminal and the source and drain terminals of the first MOS transistor is approximately 180 degrees. Due to the Miller effect, the capacitance of the MOS variable capacitor (varactor) is equivalent to approximately double the capacitance value. Thus, it is possible to provide a large ratio of a change in frequency to a change in the control voltage of the MOS varactor, and downsize the system compared with the capacitance value required to vary an equivalent frequency. The dynamic range of the control voltage is enhanced so that it is possible to provide a large frequency change width. This makes it possible to reduce the size of the second and third MOS transistors and reduce the chip size.

The invention provides a voltage-controlled oscillator comprising a plurality of the load capacitor means and the load capacitor 2 means respectively, the voltage-controlled oscillator designed to control an oscillating frequency by inputting control signals dependent of each other.

With this configuration, it is possible to increase the capacitance variable width.

The invention provides a voltage-controlled oscillator designed to input a temperature compensation control signal and an external voltage frequency control signal with high resistance coupled or a MOS transistor threshold value voltage control signal to the back gate terminal of the first, second or third MOS transistors used in the load capacitor 1 and 2 means.

With this configuration, connection is made from the back gate to the high resistance so that the capacitance value below the capacitance switching voltage between the drain and back gate terminals is reduced, thus increasing the frequency variable width and negative resistance. Variations in the capacitance value as seen from the piezoelectric vibrator can be suppressed.

The invention provides a voltage-controlled oscillator wherein the first and the second control signals are signals comprising a temperature compensation control signal and an external voltage frequency control signal superimposed one over the other and the third signal is a MOS transistor threshold voltage control signal.

With this configuration, it is possible to suppress variations in the temperature compensation of the piezoelectric vibrator and external voltage frequency.

The invention provides a voltage-controlled oscillator wherein the first and the second control signals are MOS transistor threshold voltage control signals and the third control signal is a signal comprising a temperature compensation control signal and an external voltage frequency control signal superimposed one over the other.

With this configuration, it is possible to suppress variations in temperature compensation and external voltage frequency.

The invention provides a voltage-controlled oscillator wherein a terminal to which the first or second control signal is input includes a circuit having a function to cancel the variations in temperature characteristic.

With this configuration, it is possible to cancel the variations in the temperature characteristic of a MOS transistor and enhance yield.

The invention provides a voltage-controlled oscillator wherein a terminal to which the first or second or third control signal is input includes a circuit having a filter function to remove low frequencies.

With this configuration, it is possible to remove a voltage noise component input from an input voltage thus reducing noise.

The invention provides a voltage-controlled oscillator wherein a terminal to which the first or second control signal is input includes a regulating circuit having non-volatile storage medium storing a regulating voltage.

With this configuration, a predetermined regulating threshold voltage may be stored on a non-volatile storage medium and read the voltage from the non-volatile storage medium to perform regulation, thereby performing high-accuracy regulation in a short period.

The invention provides a voltage-controlled oscillator wherein circuits including a voltage-controlled oscillator circuit are modularized together with a piezoelectric vibrator.

In this way, it is possible to minimize the capacitance value and increase the frequency valuable volume below the capacitance switching voltage from the load capacitance of the piezoelectric vibrator and frequency characteristic, thereby controlling a MOS transistor threshold voltage independently of a temperature compensation control signal and an external voltage frequency control signal to control the capacitance switching voltage and vary the frequency around an arbitrary control voltage value.

According to the invention, it is possible to enhance the frequency variable volume by minimizing the capacitance value below the capacitance switching voltage. It is also possible to control a capacitance switching voltage by controlling the MOS transistor threshold voltage independently of a temperature compensation control signal and an external voltage frequency control signal, thus varying the frequency around an arbitrary control voltage value.

It is possible to input a signal to cancel the threshold voltage and temperature characteristic of a MOS transistor independently of a temperature compensation control signal and an external voltage frequency control signal, thus facilitating the design of a temperature compensation control circuit and an external voltage frequency control circuit.

In this way, the invention provides an advantage of commercialize a voltage-controlled oscillator that uses an electrostatic capacitance between the terminals of a MOS transistor.

### BRIEF DESCRIPTION OF THE DRAWINGS

FIG. 1 is a circuit diagram showing the general configuration of a voltage-controlled oscillator according to Embodiment 1 of the invention.

FIG. 2 is a circuit diagram showing the general configuration of a voltage-controlled oscillator according to Embodiment 2 of the invention.

FIG. 3 is a circuit diagram showing an exemplary configuration of a MOS transistor according to Embodiment 2.

FIG. 4 is a circuit diagram showing an exemplary configuration of a MOS transistor according to Embodiment 2.

FIG. 5 is a circuit diagram showing the general configuration of a voltage-controlled oscillator according to Embodiment 3.

FIG. 6 is a t is a circuit diagram showing the general configuration of a voltage-controlled oscillator according to Embodiment 4.

FIG. 7 is a t is a circuit diagram showing the general configuration of a voltage-controlled oscillator according to Embodiment 5.

FIG. 8 is a circuit diagram showing the connection of the back gate terminal of a MOS transistor used in a voltage-controlled oscillator according to Embodiment 6.

FIG. 9 is a circuit diagram showing the general circuit configuration of an amplifier used in a voltage-controlled oscillator according to Embodiment 7.

FIG. 10 is a circuit diagram showing a general circuit configuration of an amplifier used in a voltage-controlled oscillator according to Embodiment 8.

FIG. 11 is a circuit diagram showing the general configuration where the connection of the resistor for removing high frequencies used in a voltage-controlled oscillator according to Embodiment 9 has been changed.

FIG. 12 is a circuit diagram showing the general configuration where the connection of the resistor for removing high frequencies used in a voltage-controlled oscillator according to Embodiment 10 has been changed.

FIG. 13 is a circuit diagram showing the general configuration where a variation cancellation circuit is added to the resistor for removing high frequencies used in a voltage-controlled oscillator according to Embodiment 11 has been changed.

FIG. 14 is a circuit diagram showing the general configuration where the connection of the resistor for removing high frequencies used in a voltage-controlled oscillator according to Embodiment 12 has been changed.

FIG. 15 is a circuit diagrams showing the general configuration of a voltage-controlled oscillator according to Embodiment 13.

FIG. 16 shows the C—V characteristic and f-V characteristic illustrating the related art embodiment 1.

FIG. 17 shows the C—V characteristic and f-V characteristic illustrating the Embodiment 1.

FIG. 18 shows the C—V characteristic and f-V characteristic illustrating the Embodiment 2.

FIG. 19 is a circuit diagram showing the general configuration of a related art voltage-controlled oscillator.

### DESCRIPTION OF THE PREFERED EMBODIMENTS

Embodiments of the invention will be described referring to drawings.

### Embodiment 1

FIG. 1 is a circuit diagram showing the general configuration of a voltage-controlled oscillator according to Embodiment 1 of the invention.

As shown in FIG. 1, a voltage-controlled oscillator according to Embodiment 1 of the invention comprises a variable capacitor 1 with a small variable volume as the load capacitor 1 and a variable capacitor 2 with a large variable volume as the load capacitor 2.

FIG. 17 shows a change characteristic corresponding to the input voltage of a capacitance provided by the variable capacitor 1 and variable capacitor 2.

As understood from FIG. 17, a composite capacitance of a capacitance value mildly changing with respect to the input voltage of the variable capacitor 1 and a capacitance value abruptly changing with respect to the input voltage of the variable capacitor 2 shows a certain change with respect to a change in capacitance and frequency.

This facilitates the design of a temperature compensation control circuit and an external voltage frequency control circuit. Further, it is possible to facilitate design by being capable of expanding the output D range of the output bias of a temperature compensation control circuit and an external voltage frequency control circuit.

### Embodiment 2

FIG. 2 is a circuit diagram showing the general configuration of a voltage-controlled oscillator according to Embodiment 2 of the invention.

As shown in FIG. 2, a voltage-controlled oscillator according to Embodiment 2 of the invention has, for example, the source and drain terminals of the first MOS transistor 13 of the load capacitor and MOS transistors 14 and 15 of the load capacitor 2 as load capacitors respectively short-circuited. The gate terminal of the first MOS transistor 13 of the load capacitor 1 and the gate terminals of the second and third MOS transistors 14 and 15 of the load capacitor 2 are connected in common and use variable capacitor elements that use an electrostatic capacitance between the gate terminal and the source and drain terminals of the first, second and third MOS transistors.

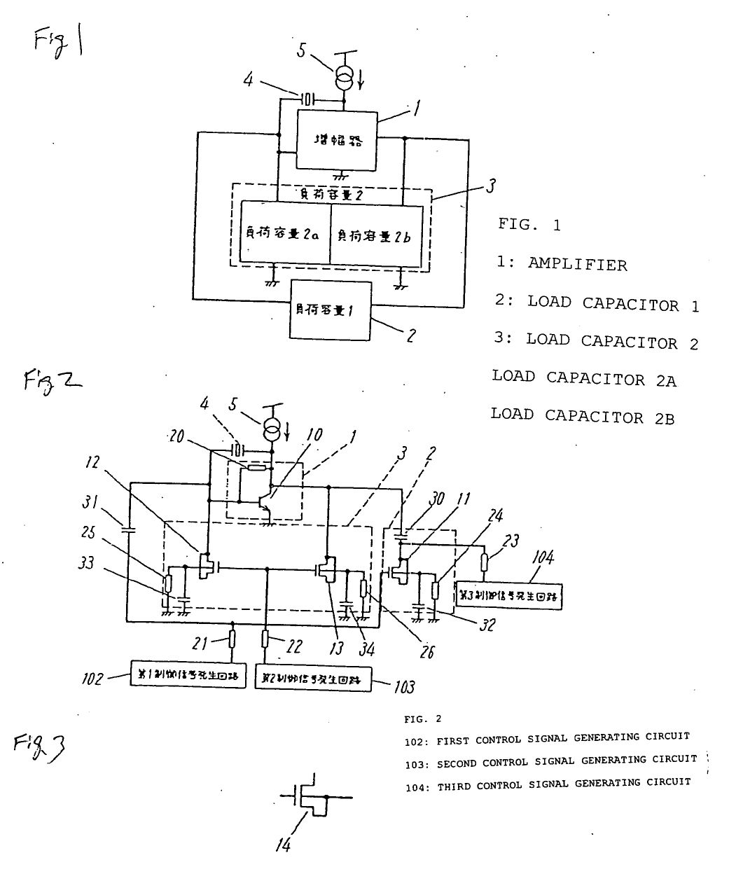

FIG. 3 shows another use example of a MOS transistor according to Embodiment 2 of the invention.

The use example of MOS transistors of the load capacitor 1 and the load capacitor 2 according to Embodiment 2 of the invention will be described in terms of the load capacitance used by the load capacitor 1. The source terminal and the back gate terminal of the first MOS transistor 13 are short-circuited. The source terminal and the back gate terminal of each of the second and third MOS transistors 14, 15 of the load capacitor 2 are short-circuited. The gate terminal of the first MOS transistor 13 of the load capacitor 1 and the gate terminals of the second and third MOS transistors 14 and 15 of the load capacitor 2 maybe connected in common and use variable capacitor elements that use an electrostatic capacitance between the gate terminal and the source and drain terminals of the first, second and third MOS transistors.

FIG. 4 shows another use example of a MOS transistor according to Embodiment 2 of the invention.

The use example of MOS transistors of the load capacitor 1 and the load capacitor 2 according to Embodiment 2 of the invention will be described in terms of the load capacitance used by the load capacitor 1. The source terminal and drain terminal of the first MOS transistor 13 are short-circuited. The source terminal of the first MOS transistor 13 and the drain terminal of the fourth MOS transistor 16 are sort-circuited. The back gate terminal of each of the first and fourth MOS transistors 13, 16 and the source terminal of the fourth MOS transistor 16 are short-circuited. The date terminals of the first and second MOS transistors 13, 16 are short-circuited. The source and drain terminals of the first MOS transistor 13, the train terminal of the second transistor 16, and the gate terminals of the first and the second MOS transistors may use variable capacitor elements that use an electrostatic capacitance.

As shown in FIG. 2, the voltage-controlled oscillator is a voltage-controlled oscillator circuit comprising: an oscillating amplifier composed of a feedback resistor 1 consisting of a feedback circuit and an amplifier 2; a crystal vibrator 3; and a load capacitor. As a load capacitor, a variable capacitor using an electrostatic capacitance generated between the drain and gate terminals and between the drain and back gate terminals of the MOS transistor is employed.

FIG. 16 shows the C—V characteristic and f-V characteristic of an electrostatic capacitance generated between the terminals of the MOS transistor. The characteristic obtained using the terminals of a MOS transistor of the related art characteristic is shown in broken lines.

As understood from FIG. 16, a capacitance C abruptly changes with a voltage obtained by adding a threshold voltage to a voltage applied to one terminal. A voltage V may be chosen arbitrarily by using a MOS transistor threshold voltage control signal applied to the other terminal. It is thus possible to arbitrarily choose a capacitance switching voltage or a voltage where a frequency switches. This makes it possible to arbitrarily determine the output bias of a temperature compensation control circuit of an external voltage frequency control circuit thus facilitating the system design.

By applying a voltage having an opposite characteristic to variations and temperature characteristic as a threshold voltage control signal of a MOS transistor, it is possible to cancel the temperature characteristic and cancel the variations and temperature characteristic of a capacitance switching voltage independently of a temperature compensation control signal and an external voltage frequency control signal, thereby facilitating the design of a temperature compensation control circuit and an external voltage frequency control circuit.

The phase difference between the gate terminal and the source and drain terminals of the MOS transistor of the load capacitor 1 according to Embodiment 2 is approximately 180 degrees. Due to the Miller effect, the capacitance of the MOS variable capacitor (varactor) is equivalent to approximately double the capacitance value. It is possible to provide a large ratio of a change in frequency to a change in the control voltage of the MOS varactor, a so-called a frequency variable sensitivity. The dynamic range of the control voltage is enhanced so that it is possible to provide a large frequency change width. This makes it possible to reduce the size of the first and fourth MOS transistors 13, 16 and reduce the chip size.

### Embodiment 3

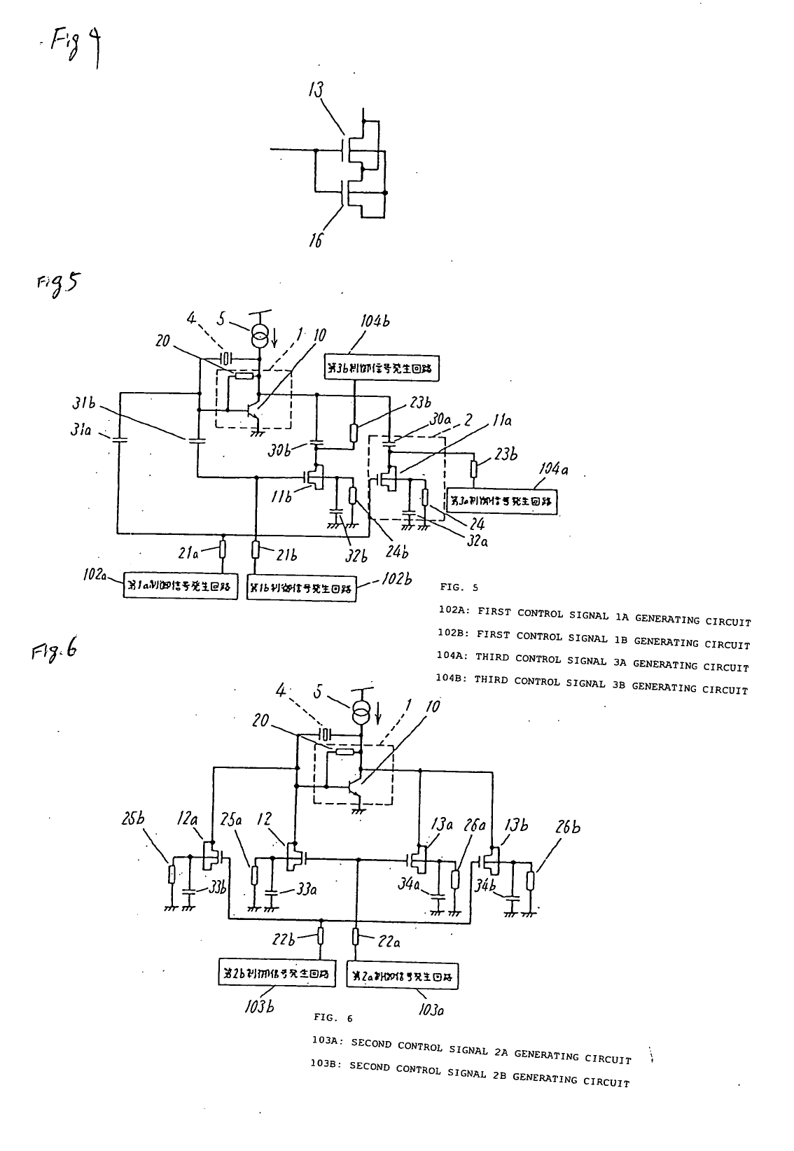

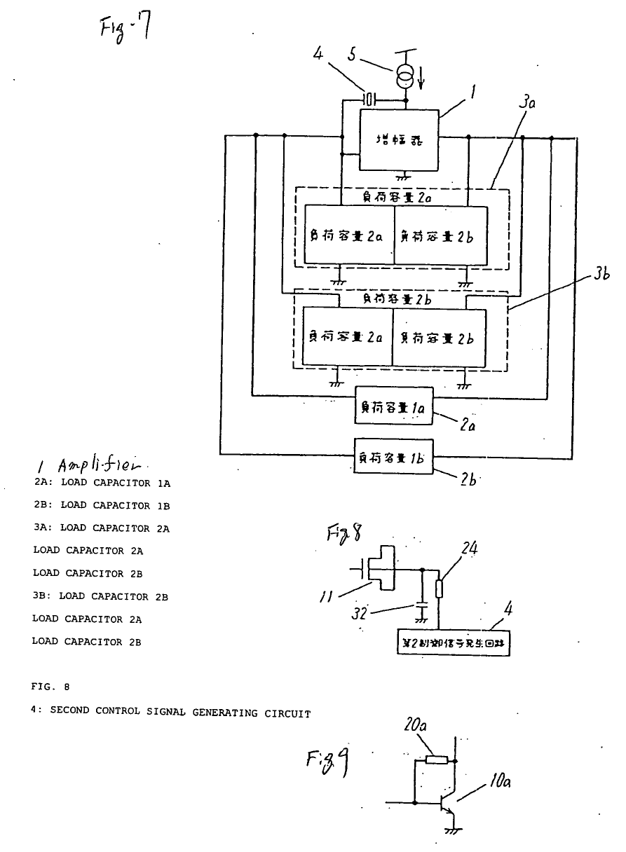

FIG. 5 is a circuit diagram showing the general configuration of a voltage-controlled oscillator according to Embodiment 3 of the invention.

Embodiment 3 includes a plurality of the load capacitors 1 of Embodiment 2 connected together as shown in FIG. 5. The parts of Embodiment 3 are the same as those of Embodiment 2. Corresponding description is omitted and a same part is given a same sign.

With this configuration, the frequency variable range is reduced compared with the voltage-controlled oscillator according to Embodiment 2. The area of the MOS size used as the load capacitor 1 is small. To the gate terminal and the source and drain terminals of the MOS transistor are input a MOS transistor threshold voltage control signal or a temperature compensation control signal and an external voltage frequency control signal via high-frequency resistors 21, 22, 23. This reduces variations in the temperature characteristic of an element itself and allows external frequency control. By connecting a plurality of the load capacitors 1 and providing the load capacitors with individual control signals, a wide frequency variable range is ensured.

In this embodiment, a MOS transistor is used as a variable capacitor so that it is possible to vary frequencies by at least 100 ppm with respect to a control voltage. This ensures a frequency change width sufficient to perform temperature compensation and external voltage frequency control. Moreover, it is not necessary to increase the number of elements, which allows system downsizing and supports introduction of a compact crystal vibrator.

### Embodiment 4

FIG. 6 is a circuit diagram showing the general configuration of a voltage-controlled oscillator according to Embodiment 4 of the invention.

Embodiment 4 includes a plurality of the load capacitors 2 of Embodiment 2 connected together as shown in FIG. 6. The parts of Embodiment 4 are the same as those of Embodiment 2. Corresponding description is omitted and a same part is given a same sign.

With this configuration, the variable voltage range is reduced compared with the voltage-controlled oscillator according to Embodiment 2. However, it is possible to enhance the frequency sensitivity and reduces the parasitic capacitance obtained when a MOS transistor is OFF thus attaining reduction of the activation time as one of the important goals. To the gate terminal and the source and drain terminals of a MOS used as the load capacitor 2 is input a MOS transistor threshold voltage control signal or a temperature compensation control signal and an electrostatic capacitance. This reduces variations in the temperature characteristic of an element itself and allows external frequency control. By connecting a plurality of the load capacitors 1 and providing the load capacitors with individual control signals, a wide frequency variable range is ensured.

In this embodiment also, a MOS transistor is used as a variable capacitor so that it is possible to vary frequencies by at least 100 ppm with respect to a control voltage. This ensures a frequency change width sufficient to perform temperature compensation and external voltage frequency control.

### Embodiment 5

FIG. 7 is a circuit diagram showing the general configuration of a voltage-controlled oscillator according to Embodiment 5 of the invention.

Embodiment 5 includes a plurality of the load capacitors 1 and the load capacitors 2 of Embodiment 2 connected together as shown in FIG. 7. The parts of Embodiment 5 are the same as those of Embodiment 2. Corresponding description is omitted and a same part is given a same sign.

With this configuration, the parasitic capacitance obtained when a MOS transistor is OFF is larger than that obtained with the voltage-controlled oscillator according to Embodiment 2. A MOS transistor threshold voltage control signal or a temperature compensation control signal and an electrostatic capacitance are input as a control signal for the MOS transistor so that variations in the temperature characteristic of an element itself is reduced and external frequency control is allowed. By individually controlling respective load capacitors, control by way of a wide voltage range is enabled.

In this embodiment also, a MOS transistor is used as a variable capacitor so that it is possible to vary frequencies by at least 100 ppm with respect to a control voltage. This ensures a frequency change width sufficient to perform temperature compensation and external voltage frequency control.

### Embodiment 6

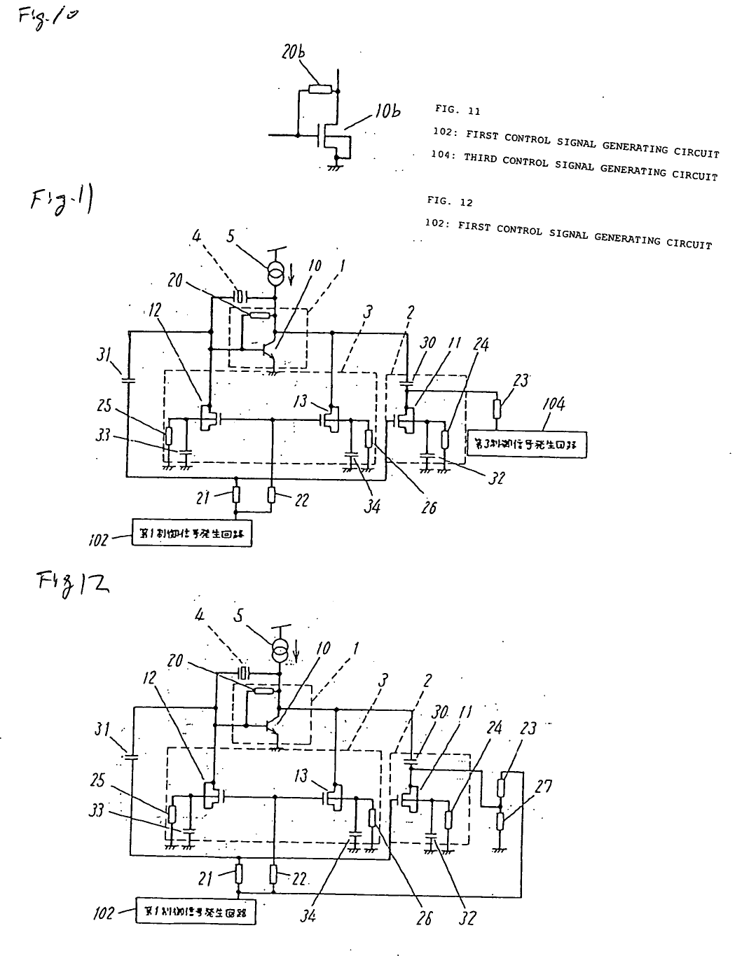

FIG. 8 is a circuit diagram showing the connection of the back gate terminal of a MOS transistor used in a voltage-controlled oscillator according to Embodiment 2 of the invention.

In Embodiment 6, as shown in FIG. 8, one end of each of a capacitor 32 and a resistor 24 is connected to the back gate terminal of a MOS transistor 11 used as a load capacitor and the other end of the capacitor is grounded while the other end of the resistor can be voltage-controlled. This connected capacitor is the same for a parasitic capacitance generated between a back gate and a well.

With this configuration, by individually controlling the MOS transistor to be used, the parasitic capacitance obtained when the MOS transistor is ON is increased thus enhancing the frequency variable range. The resistor connected in common with the capacitor has a resistance value sufficiently greater than the impedance component of the capacitance value so that it is possible to fix the potential of the contact to which the back gate terminal, the capacitor and the resistor are connected in common. Thus, by reducing a minute change in the capacitance of the MOS transistor of the variable capacitor during circuit operation, stability of voltage activation is ensured.

That is, according to this embodiment, it is possible to provide stable oscillation in an oscillator using a MOS transistor as a variable capacitor even in the presence of a change with time.

FIG. 9 shows a general circuit configuration of an amplifier used in a voltage-controlled oscillator according to Embodiment 7 of the invention.

As shown in FIG. 9, Embodiment 7 uses a bipolar transistor as the amplifier according to Embodiment 2 of the invention.

With this configuration, the drain/source potential of the second and third MOS transistors 12, 13 of the load capacitor 2 is determined by the base potential and the collector potential of the bipolar transistor 10a, and a change in capacitance takes place with the gate voltage. On this occasion, the difference between the base potential and the collector potential of the bipolar transistor of the amplifier causes a change in the capacitance switching voltage of the MOS transistor of the load capacitor 2. This allows expansion of a voltage width where frequencies vary with respect to the voltage across gates.

According to this embodiment, it is possible to ensure a wide frequency variable range with respect to an input voltage.

### Embodiment 8

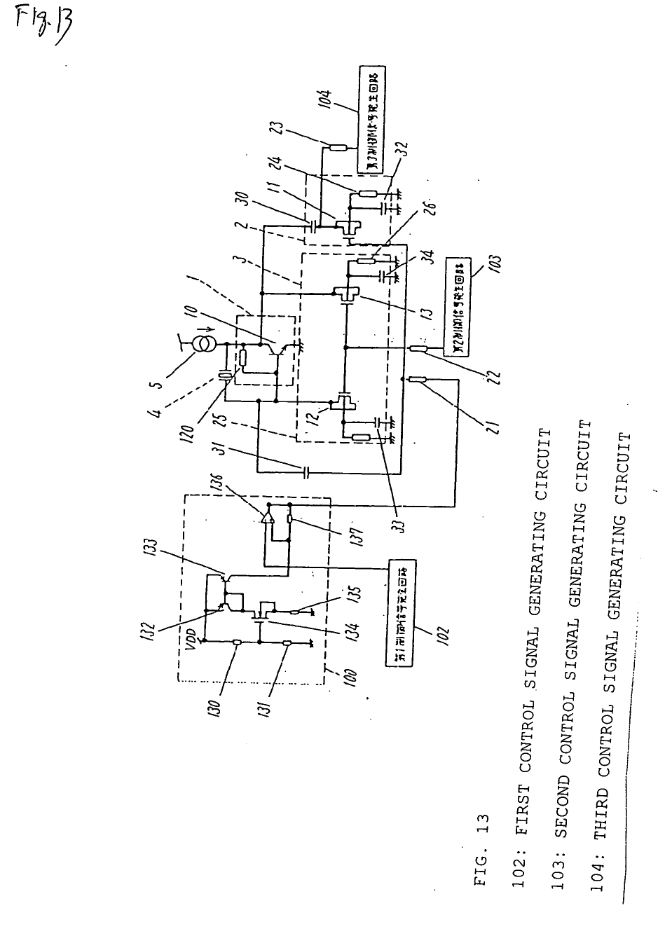

FIG. 10 shows a general circuit configuration of an amplifier used in a voltage-controlled oscillator according to Embodiment 8 of the invention.

In Embodiment 8, as shown in FIG. 10, the amplifier according to Embodiment 2 of the invention is a circuit composed of a CMOS transistor.

With this configuration, the drain/source potential of the second and third MOS transistors of the load capacitor 2 is determined by the gate potential and the drain potential of the CMOS transistor 10b, and a change in capacitance takes place with the gate voltage. On this occasion, the difference between the base potential and the collector potential of the bipolar transistors 10b, 12b of the amplifier causes a change in the capacitance switching voltage of the MOS transistor of the load capacitor 2. This allows expansion of the frequency varying sensitivity with respect to the gate voltage.

According to this embodiment, it is possible to ensure a wide frequency variable range with respect to an input voltage.

### Embodiment 9

FIG. 11 is a circuit diagram where the load capacitor 1 used in the voltage-controlled oscillator according to Embodiment 2 of the invention and the resistor for removing high-frequencies connected to the gate of the load capacitor 2 are connected in common.

In Embodiment 9, as shown in FIG. 11, a voltage may be commonly applied to the gate of the load capacitor 2 and the gate of the load capacitor 2 of Embodiment 2 of the invention. The voltage applied to the gates of the load capacitor 1 and the load capacitor 2 is used as a signal where a temperature compensation control signal and an external voltage frequency control signal are superposed one over the other.

With this configuration, it is possible to simultaneously control a temperature compensation control signal and an external voltage frequency control signal.

### Embodiment 10

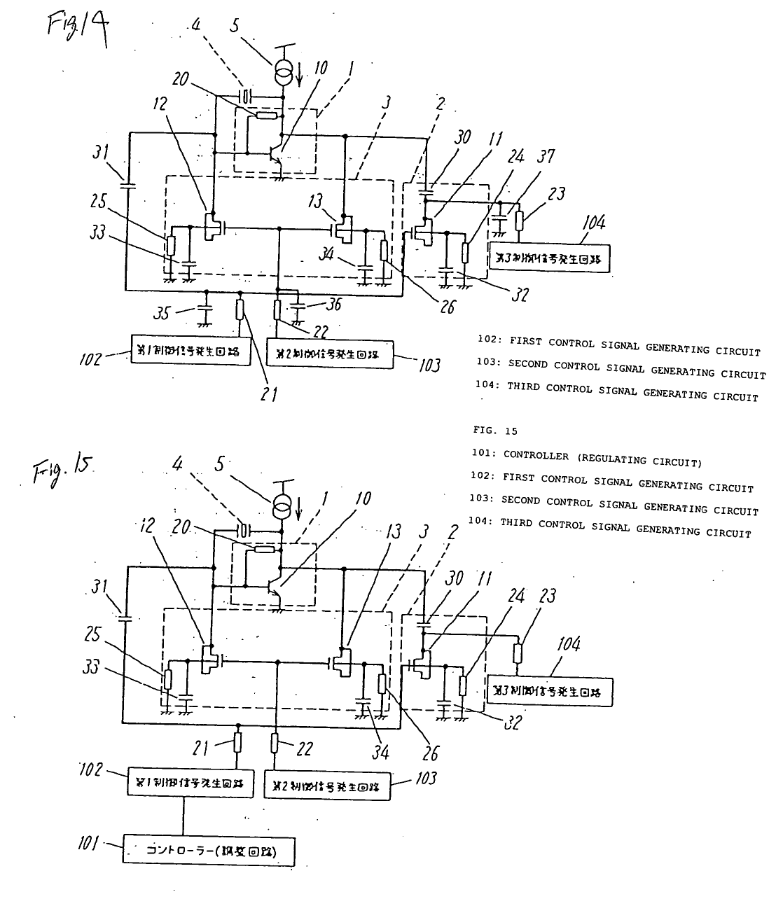

FIG. 12 is a circuit diagram where the load capacitor 1 used in the voltage-controlled oscillator according to Embodiment 2 of the invention and the resistor for removing high frequencies connected to the gate of the load capacitor 2 and the drain of the load capacitor 3 are individually connected.

In Embodiment 10, as shown in FIG. 12, a voltage may be individually applied to each of the gate of the load capacitor 2 and the gate of the load capacitor 2 of Embodiment 2 of the invention as well as the drain of the load capacitor 3. The voltage applied to the gates of the load capacitor 1 and the load capacitor 2 is used as a signal where a temperature compensation control signal and an external voltage frequency control signal are superposed one over the other. The voltage applied to the drain of the load capacitor 3 is used as a signal to control a threshold variation temperature characteristic.

With this configuration, it is possible to simultaneously control a temperature compensation control signal and an external voltage frequency control signal.

### Embodiment 1

FIG. 13 is a circuit diagram where a cancellation circuit for canceling the temperature characteristic of a MOS transistor is added to the resistor for removing high frequencies connected to the gates of the load capacitor 1 and the load capacitor 2 used in the voltage-controlled oscillator according to Embodiment 2 of the invention.

In Embodiment 11, as shown in FIG. 13, a resistor for removing high frequencies is connected to the terminal applied to the gates of the load capacitor 1 and the load capacitor 2 and the drain terminal of the load capacitor 2. To any of the gates of the load capacitor 1 and the load capacitor 2 or drain terminal of the load capacitor 2 is input a third control signal where a temperature compensation control signal or an electrostatic capacitance or a variation signal is superimposed one over the other via a cancellation circuit 100 for canceling the temperature characteristic.

With this configuration, it is possible to independently control signals to perform temperature compensation control of a piezoelectric vibrator and cancel the temperature characteristic of a circuit element such as a first, second and third MOS transistors and variations in the external voltage frequency, while controlling the capacitance switching voltage in a similar fashion to the first and second embodiments.

### Embodiment 12

FIG. 14 shows a configuration where a filter function for removing noise is connected to the gate terminal of a MOS transistor used in the voltage-controlled oscillator according to Embodiment 2 of the invention.

In Embodiment 12, as shown in FIG. 14, a filter function composed of a resistor for removing high frequencies and a capacitor is added to the gate terminal and drain terminal of the MOS transistors of the load capacitors 1 and 2. The parts of Embodiment 12 are the same as those of Embodiment 2. Corresponding description is omitted and a same part is given a same sign.

With this configuration, it is possible to prevent a voltage noise input from the outside of the voltage-controlled oscillator from being amplified in the voltage-controlled oscillator thus keeping a stable noise level.

### Embodiment 13

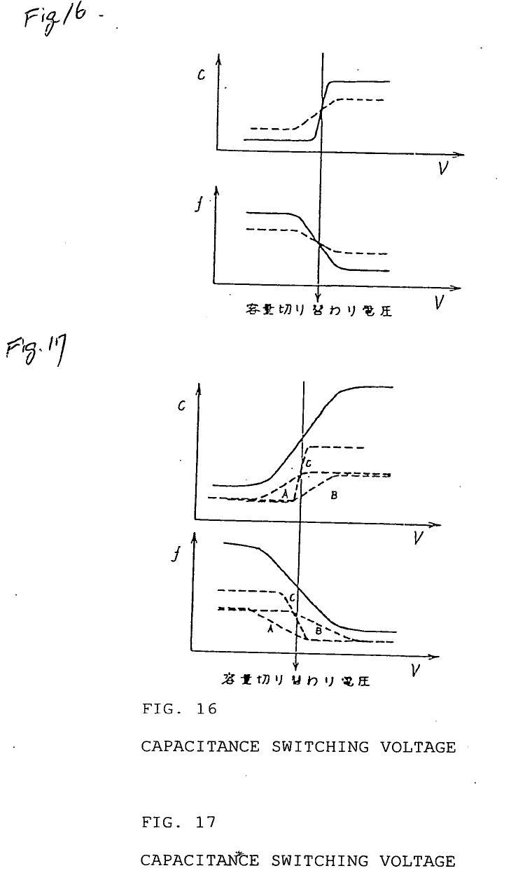

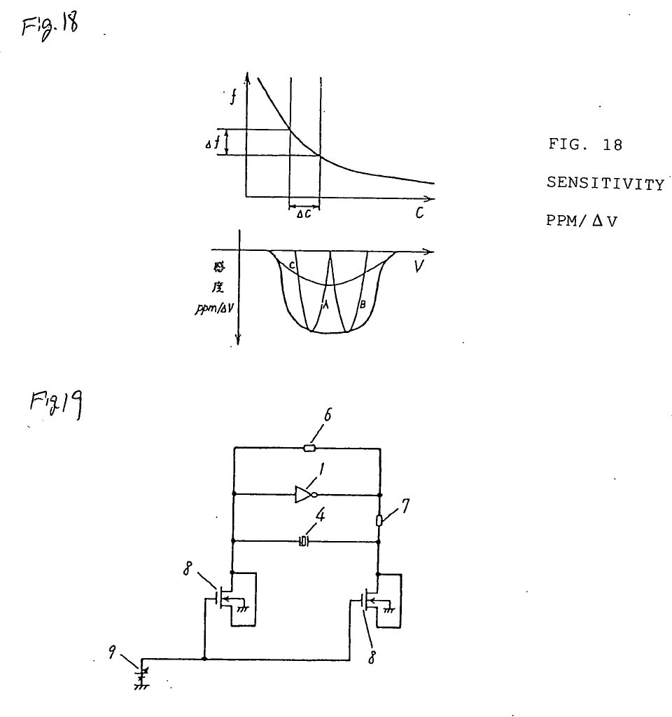

FIG. 15 is a circuit diagram showing the general configuration of a voltage-controlled oscillator according to Embodiment 6 of the invention.

In Embodiment 13, as shown in FIG. 15, regulation is made by using a value output from a regulating circuit that previously stores a voltage to be input.

This method is made available by storing a regulation value into the PROM of a non-volatile storage medium at shipment so that a capacitance switching voltage to cancel variations in the threshold value of a MOS transistor in the diffused manufacturing process may be applied to a capacitance switching terminal or regulated. Or, this method is made available by storing a temperature compensation control signal, an external voltage frequency control signal or a variation signal.

While an NMOS transistor has been described as an example in the foregoing embodiments, a PMOS transistor may be also used.

The voltage-controlled oscillator according to the invention is capable of controlling an oscillating frequency by using an electrostatic capacitance generated between the source and drain terminals and the gate terminal of a MOS transistor where the source and drain terminals are short-circuited as a variable capacitor, so that it is useful as a temperature-compensated crystal oscillator that is based on voltage control.

What is claimed is:

1. A voltage-controlled oscillator comprising:
an amplifier;
a piezoelectric vibrator; and
a fist load capacitor and a second load capacitor arranged between both terminals of said piezoelectric vibrator;
wherein said first load capacitor is composed of a variable capacitor with a small change in capacitance with respect to an input voltage and said second load capacitor is composed of a variable capacitor with a large change in capacitance with respect to an input voltage.

2. A voltage-controlled oscillator comprising:
an amplifier;
a piezoelectric vibrator; and
a first load capacitor and a second load capacitor arranged between both terminals of said piezoelectric vibrator;
wherein said first load capacitor is composed of a first MOS transistor consisting of first and second DC cut capacitors and said second load capacitor includes load capacitor composed of a second and third MOS transistors; and
wherein a first control signal input to the gate terminal of said MOS transistor of said first load capacitor via a first resistor for removing high frequencies, a third control signal input to the drain terminal via a third resistor for removing high frequencies, and a second control signal input to the gate terminal of said MOS transistor of said load capacitor via a second resistor for removing high frequencies are used to control an oscillating frequency.

3. The voltage-controlled oscillator according to claim 2, further comprising:
means composed of said first load capacitor and capacitor means as said second load capacitor with a change in capacitance different from that of said first load capacitor.

4. The voltage-controlled oscillator according to claim 2, further comprising:
means composed of said second load capacitor and capacitor means as said first load capacitor with a change in capacitance different from that of said second load capacitor.

5. The voltage-controlled oscillator according to claim 1, wherein a plurality of said first and second load capacitors are connected in parallel.

6. The voltage-controlled oscillator according to claim 2, wherein a plurality of said first and second load capacitors are connected in parallel.

7. The voltage-controlled oscillator according to claim 1, wherein a fourth control signal is input to the back gate electrode of the MOS transistor of said load capacitor means via a resistor for removing high frequencies.

8. The voltage-controlled oscillator according to claim 2, wherein a fourth control signal is input to the back gate electrode of the MOS transistor of said load capacitor means via a resistor for removing high frequencies.

9. The voltage-controlled oscillator according to claim 1, wherein said amplifier is composed of a bipolar transistor.

10. The voltage-controlled oscillator according to claim 2, wherein said amplifier is composed of a bipolar transistor.

11. The voltage-controlled oscillator according to claim 1, wherein said amplifier is composed of a CMOS transistor.

12. The voltage-controlled oscillator according to claim 2, wherein said amplifier is composed of a CMOS transistor.

13. The voltage-controlled oscillator according to claim 2, wherein said first control signal is combined with said second control signal to allow either said third control signal or an external voltage frequency control signal and a temperature compensation control signal to be input.

14. The voltage-controlled oscillator according to claim 2, wherein said first control signal, said second control signal and said third control signal are signals where a temperature compensation control signal and an external voltage frequency control signal are superposed one over the other.

15. The voltage-controlled oscillator according to claim 2, wherein a terminal to which said first control signal, said second control signal or said third control signal is input includes a circuit having a function to cancel variations in the MOS transistor threshold voltage or a function to cancel temperature characteristic.

16. The voltage-controlled oscillator according to claim 2, wherein a filter function composed of a capacitor and a resistor is added between said first control signal and said second control signal and the gates of the first, second and third MOS transistors in said load capacitors.

17. The voltage-controlled oscillator according to claim 2, wherein a terminal to which said first control signal, said second control signal or said third control signal is input includes a regulating circuit having a non-volatile storage medium that stores a regulating voltage.
